(19) United States
(12) Patent Application Publication
(10) Pub. No.: US 2025/0125205 A1
(43) Pub. Date: Apr. 17, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Jinwoo Park, Suwon-si (KR); Kiseok Kim, Suwon-si (KR); Jinyoung Kim, Suwon-si (KR); Jihye Shim, Suwon-si (KR)

(21) Appl. No.: 18/674,416

(22) Filed: May 24, 2024

(30) Foreign Application Priority Data
Oct. 16, 2023 (KR) 10-2023-0137966

(51) Int. Cl. H01L 23/29; H01L 23/00; H01L 23/31; H01L 23/48

(52) U.S. Cl. CPC H01L 23/295; H01L 23/3107; H01L 23/481; H01L 24/08; H01L 2224/08145

(57) ABSTRACT

A semiconductor package includes a first semiconductor chip including first pads, a second semiconductor chip including second pads in contact with the first pads, and through-electrodes electrically connected to the second pads and extending to a rear surface opposite to the front surface, a dielectric layer covering at least portions of the respective first and second semiconductor chips and having an inner surface facing the first and second semiconductor chips and an outer surface opposite the inner surface, and bump structures on a portion of the outer surface of the dielectric layer and electrically connected to the through-electrodes. The dielectric layer includes inorganic particles, and polymer chains bonded to at least one sides of the respective inorganic particles and connected toward the inner surface and the outer surface via the inorganic particles.

### CROSS-REFERENCE TO RELATED APPLICATION(S)

This application claims the benefit under 35 USC 119 of priority to Korean Patent Application No. 10-2023-0137966 filed in the Korean Intellectual Property Office on Oct. 16, 2023, the entire disclosure of which is incorporated herein by reference.

### BACKGROUND

Semiconductor devices installed in electronic devices require high performance and high capacity as well as miniaturization. To this end, a semiconductor package interconnecting semiconductor chips stacked in a vertical direction using a through-electrode (for example, Through Silicon Via) is being developed.

### SUMMARY

In general, in some aspects, the present disclosure is directed toward a semiconductor package having simplified processes and improved reliability, and a method of manufacturing the same.

In general, according to some aspects of the present disclosure, a semiconductor package includes a first semiconductor chip including first pads; a second semiconductor chip including second pads disposed on a front surface facing the first semiconductor chip and in contact with the first pads, and through-electrodes electrically connected to the second pads and extending to a rear surface opposite to the front surface; a dielectric layer covering at least portions of the respective first and second semiconductor chips and having an inner surface facing the first and second semiconductor chips and an outer surface opposite the inner surface; and bump structures on a portion of the outer surface of the dielectric layer and electrically connected to the through-electrodes. The dielectric layer includes inorganic particles, and polymer chains bonded to at least one sides of the respective inorganic particles and connected toward the inner surface and the outer surface via the inorganic particles.

According to some aspects of the present disclosure, a semiconductor package includes a first semiconductor chip including first pads; a second semiconductor chip below the first semiconductor chip and including second pads in contact with the first pads and through-electrodes electrically connected to the second pads; a dielectric layer covering at least portions of the respective first and second semiconductor chips; and bump structures below the second semiconductor chip and electrically connected to the through-electrodes. The dielectric layer is a nanocomposite of inorganic particles and polymer chains combined with each other.

According to some aspects of the present disclosure, a semiconductor package includes a first semiconductor chip including first pads; a second semiconductor chip below the first semiconductor chip and including second pads in contact with the first pads and through-electrodes electrically connected to the second pads; a dielectric layer below the first semiconductor chip and surrounding portions of a side surface of the second semiconductor chip and the through-electrodes protruding from a rear surface of the second semiconductor chip; and bump structures below the second semiconductor chip and electrically connected to the through-electrodes. The dielectric layer includes polymer chains interconnected through inorganic particles.

According to some aspects of the present disclosure, a method of manufacturing a semiconductor package includes preparing a semiconductor wafer including first pads; attaching a preliminary semiconductor chip including second pads disposed on a front surface and a plurality of preliminary through-electrodes buried in a preliminary substrate to the semiconductor wafer; etching the preliminary substrate to allow at least a portion of each of the plurality of preliminary through-electrodes to be exposed to a rear surface of the preliminary semiconductor chip; forming a preliminary dielectric layer covering the at least a portion of each of the plurality of preliminary through-electrodes exposed from the rear surface of the preliminary semiconductor chip and the preliminary substrate, the preliminary dielectric layer being formed by a spin coating process; polishing the preliminary dielectric layer and the plurality of preliminary through-electrodes and forming a planar surface formed of a dielectric layer and a plurality of through-electrodes; and forming bump structures on the planar surface.

### BRIEF DESCRIPTION OF THE DRAWINGS

Example implementations will be more clearly understood from the following detailed description, taken in conjunction with the accompanying drawings.

FIG. 1A is a cross-sectional view of an example of a semiconductor package according to some implementations, and FIG. 1B is a plan view taken along line I-I′ of FIG. 1A according to some implementations.

FIGS. 2A to 2B are diagrams of an example of a dielectric layer according to some implementations, and FIG. 2C is a graph of an example of heat conduction characteristics of a nanocomposite according to some implementations.

FIGS. 3A to 3C are diagrams of examples of self-healing characteristics of a dielectric layer according to some implementations.

FIGS. 4A to 4E are cross-sectional views of an example of a method of manufacturing the semiconductor package illustrated in FIG. 1A according to some implementations.

FIG. 5 is a cross-sectional view of an example of a semiconductor package according to some implementations.

FIG. 6 is a cross-sectional view of an example of a semiconductor package according to some implementations.

FIG. 7 is a cross-sectional view of an example of a semiconductor package according to some implementations.

FIG. 8 is a cross-sectional view of an example of a semiconductor package according to some implementations.

### DETAILED DESCRIPTION

Hereinafter, example implementations will be described in detail with reference to the accompanying drawings, Unless otherwise specified, in the present disclosure, terms such as ‘upper,’ ‘upper surface,’ ‘lower,’ ‘lower surface,’ ‘side’ and the like are based on the drawings, and actually, may vary depending on the direction in which the components are disposed.

Additionally, ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Additionally, terms referenced by a specific ordinal number (for example, “first” in a particular claim) may be described elsewhere with a different ordinal number (for example, “second” in the specification or another claim).

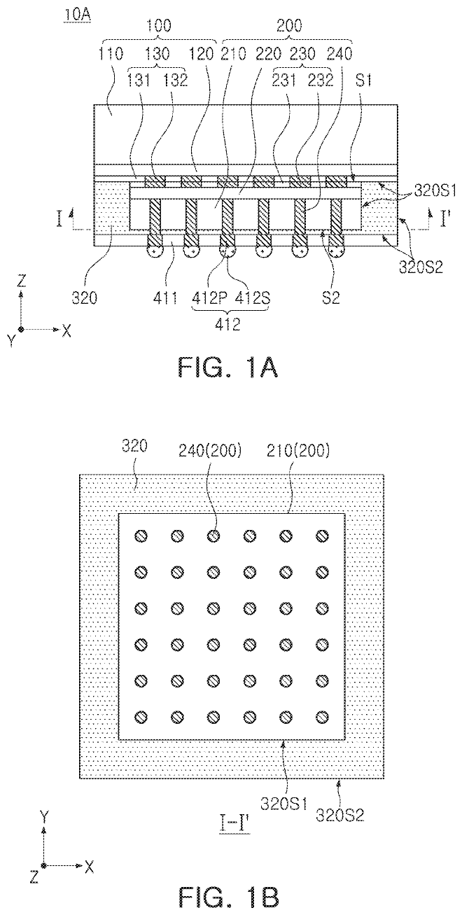

FIG. 1A is a cross-sectional view of a semiconductor package according to some implementations, and FIG. 1B is a plan view taken along line I-I′ of FIG. 1A according to some implementations.

In FIGS. 1A and 1B, a semiconductor package 10A may include a first semiconductor chip 100, a second semiconductor chip 200, and a dielectric layer 320. In some implementations, the semiconductor package 10A may further include bump structures 412.

In some implementations, an active surface of the first semiconductor chip 100 and an active surface of the second semiconductor chip 200 may be bonded to each other to significantly reducing a signal transmission path between the first semiconductor chip 100 and the second semiconductor chip 200. The first semiconductor chip 100 and the second semiconductor chip 200 may be logic chips including a central processor (CPU), a graphics processor (GPU), a field programmable gate array (FPGA), a digital signal processor (DSP), a cryptographic processor, a microprocessor, a microcontroller, an analog-to-digital converter, and the like, or memory chips including volatile memory (for example, a DRAM), a non-volatile memory (for example, a ROM and a flash memory), and the like. For example, the first semiconductor chip 100 may include a logic circuit, such as an application specific semiconductor (ASIC), and the second semiconductor chip 200 may include a cache memory circuit that provides cache information to the first semiconductor chip 100. The size of the second semiconductor chip 200 may be smaller than the size of the first semiconductor chip 100. For example, the width of the first semiconductor chip 100 may be larger than the width of the second semiconductor chip 200.

Additionally, the first semiconductor chip 100 and the second semiconductor chip 200 may be directly bonded and combined without a separate connecting member (for example, a solder bump, a copper post, or the like). This structure may be referred to as direct bonding, hybrid bonding, formed of metal bonding by pads bonded to each other and dielectric bonding by insulating layers bonded to each other, or the like.

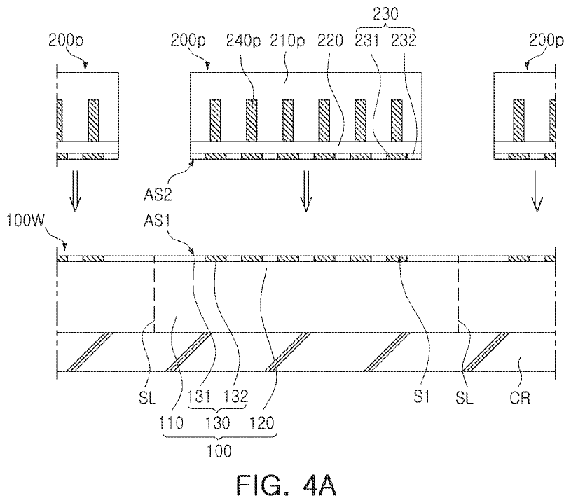

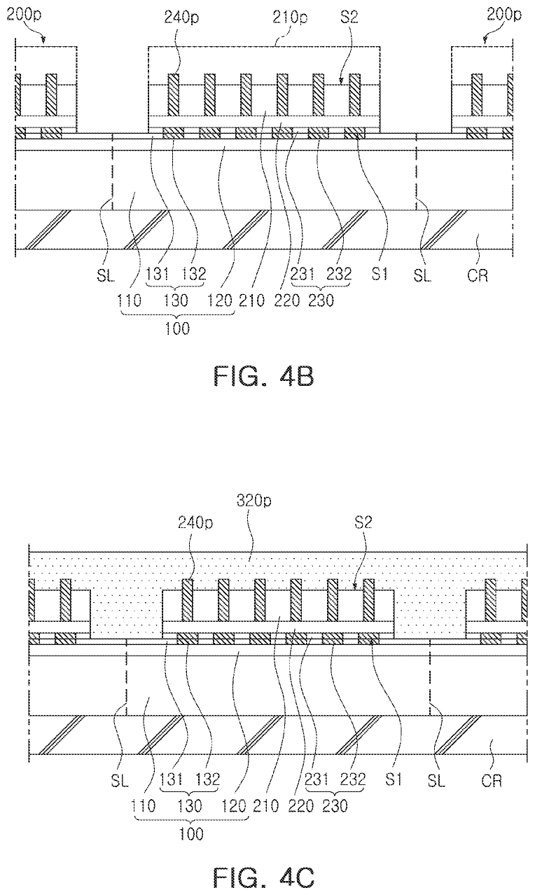

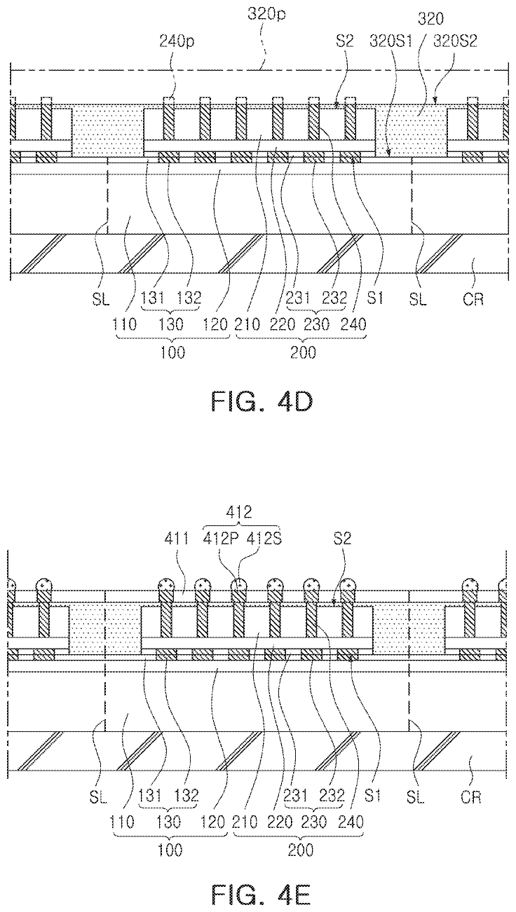

Additionally, the dielectric layer 320 may be a nanocomposite containing inorganic particles and polymer chains. According to some implementations, as the dielectric layer 320 is formed using a polymer solution to which inorganic particles to form a nanocomposite are added, difficulty of the process may be reduced and Turn Around Time (TAT) may be reduced (see FIG. 4C). The dielectric layer 320 includes inorganic particles connecting polymer chains, and may thus have improved heat conduction properties, compared to polymer resins that may be spin-coated. In addition, the dielectric layer 320 formed of nanocomposite has self-healing properties against cracks, and thus the reliability of the semiconductor package 10A may be improved.

Hereinafter, respective components of the semiconductor device 10A according to example embodiments will be described in detail.

The first semiconductor chip 100 may include a first substrate 110, a first circuit layer 120, a first insulating layer 131, and first pads 132 (or ‘first bonding layer 130’). The first semiconductor chip 100 may have a flat lower surface provided by the first insulating layer 131 and the first pads 132. The first substrate 110 may be a semiconductor wafer including a semiconductor element, such as silicon and germanium, or a compound semiconductor, such as silicon carbide (SiC), gallium arsenide (GaAs), indium arsenide (InAs), and indium phosphide (InP). The first substrate 110 may have an active surface (for example, a surface facing the first circuit layer 120) having an active region doped with impurities, and an inactive surface opposite thereto.

The first circuit layer 120 may be disposed on the active surface of the first substrate 110. The first circuit layer 120 may include an integrated circuit comprised of individual devices formed on the active surface of the first substrate 110, and an interconnection structure electrically connecting the individual elements to the first pads 132. The individual elements may include FETs such as planar FETs or FinFETs, memory devices such as flash memory, DRAM, SRAM, EEPROM, PRAM, MRAM, FeRAM and RRAM, logic elements such as AND, OR, NOT, and the like, and various active and/or passive elements such as system LSI, CIS, and MEMS. The interconnection structure may be formed as a multilayer structure including interconnection patterns and vias formed of, for example, aluminum (Al), gold (Au), cobalt (Co), copper (Cu), nickel (Ni), lead (Pb), tantalum (Ta), tellurium (Te), titanium (Ti), tungsten (W) or combinations thereof.

The first insulating layer 131 may be disposed below the first circuit layer 120 and may be formed to surround the first pads 132. The first insulating layer 131 may include a material that may be bonded to a second insulating layer 231 of the second semiconductor chip 200, for example, at least one of silicon oxide (SiO), silicon nitride (SiN), and silicon carbonitride (SiCN). For example, at least a portion of the first insulating layer 131 may be bonded to the second insulating layer 231 to form a bonding surface between the first semiconductor chip 100 and the second semiconductor chip 200.

The first pads 132 may be connection terminals electrically connected to the integrated circuit of the first circuit layer 120. The first pads 132 may be connected to second pads 232 of the second semiconductor chip 200. The first pads 132 may include any one of copper (Cu), nickel (Ni), titanium (Ti), aluminum (Al), gold (Au), and silver (Ag), or alloys thereof. The first pads 132 together with the first insulating layer 131 may form a bonding surface between the first semiconductor chip 100 and the second semiconductor chip 200. A barrier layer containing at least one of titanium (Ti), titanium nitride (TiN), tantalum (Ta), and tantalum nitride (TaN) may be formed between the first insulating layer 131 and the first pads 132.

The second semiconductor chip 200 may include a second substrate 210, a second circuit layer 220, a second insulating layer 231, the second pads 232 (or a ‘second bonding layer 230’), and through-electrodes 240. The second semiconductor chip 200 may be provided by the second insulating layer 231 and the second pads 232, and may have a flat upper surface in contact with the lower surface of the first semiconductor chip 100. In some implementations, the second semiconductor chip 200 may be provided in fewer or larger numbers than numbers illustrated in the drawings. For example, the second semiconductor chip 200 may be provided as two or more semiconductor chips disposed horizontally below the first semiconductor chip 100. Additionally, in some implementations, the second semiconductor chip 200 may be provided as a plurality of semiconductor chips stacked below the first semiconductor chip 100 in the vertical direction (Z-axis direction).

Since the second semiconductor chip 200 may have a structure substantially the same as or similar to the structure of the first semiconductor chip 100, identical or similar components are indicated by identical or similar reference numerals, and repeated descriptions of the same components are omitted below. For example, the second substrate 210 and the second circuit layer 220 have the same or similar characteristics as the above-described first substrate 110 and the first circuit layer 120, and corresponding components are indicated with similar reference numbers and overlapping descriptions are omitted.

The second insulating layer 231 may be formed to surround the second pads 232 by being disposed on the second circuit layer 220. The second insulating layer 231 may include a material that may be bonded to and combined with the first insulating layer 131, for example, at least one of silicon oxide (SiO), silicon nitride (SiN), and silicon carbonitride (SiCN).

The second pads 232 may be connection terminals disposed on a front surface S1 facing the first semiconductor chip 100 and electrically connected to the integrated circuit of the second circuit layer 220. The second pads 232 together with the second insulating layer 231 may form a bonding surface between the first semiconductor chip 100 and the second semiconductor chip 200. The second pads 232 may include any one of copper (Cu), nickel (Ni), titanium (Ti), aluminum (Al), gold (Au) and silver (Ag), or alloys thereof. For example, the second pads 232 may be bonded and combined with the first pads 132.

The through-electrodes 240 are electrically connected to the second pads 232 and may extend to a rear surface (S2) opposite to the front surface (S1). The through-electrodes 240 may penetrate through the second substrate 210 and protrude to the rear surface S2 of the second substrate 210. The through-electrodes 240 may be electrically connected to the bump structures 412. The through-electrodes 240 may include a via plug and a side barrier film (not illustrated) surrounding the side of the via plug. The via plug may include, for example, tungsten (W), titanium (Ti), aluminum (Al), or copper (Cu), and may be formed by a plating process, a PVD process, or a CVD process. The side barrier film may include titanium (Ti), titanium nitride (TiN), tantalum (Ta), or tantalum nitride (TaN), and may be formed by a plating process, a PVD process, or a CVD process. A side insulating film containing an insulating material (for example, High Aspect Ratio Process (HARP) oxide), for example, such as silicon oxide, silicon nitride, or silicon oxynitride may be formed between the through-electrodes 240 and the second substrate 210.

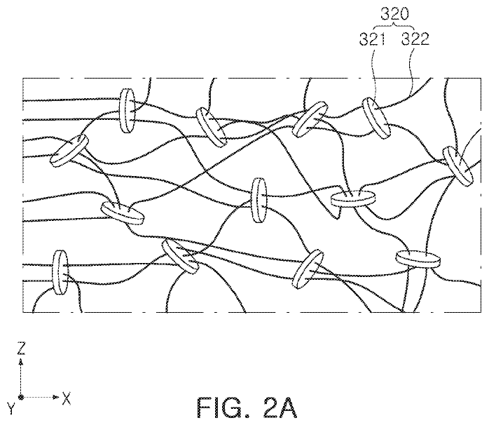

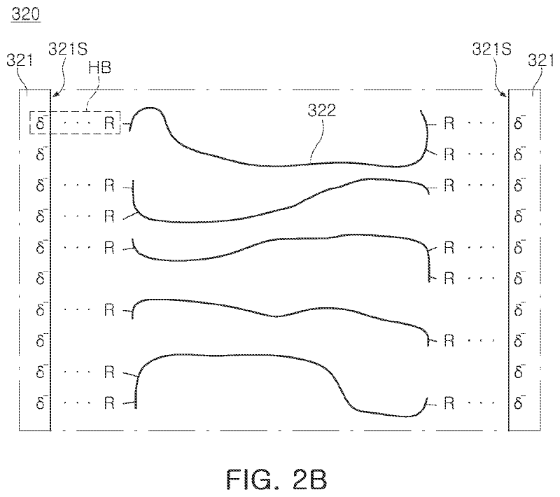

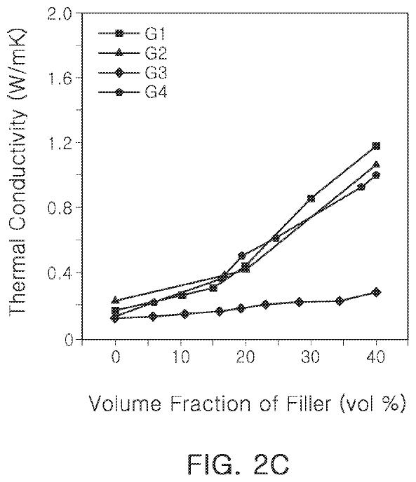

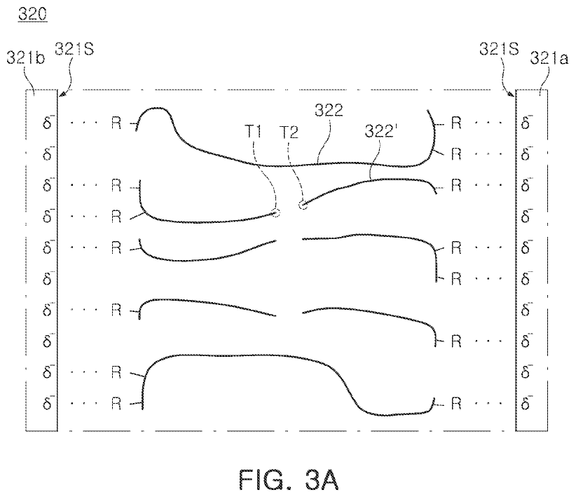

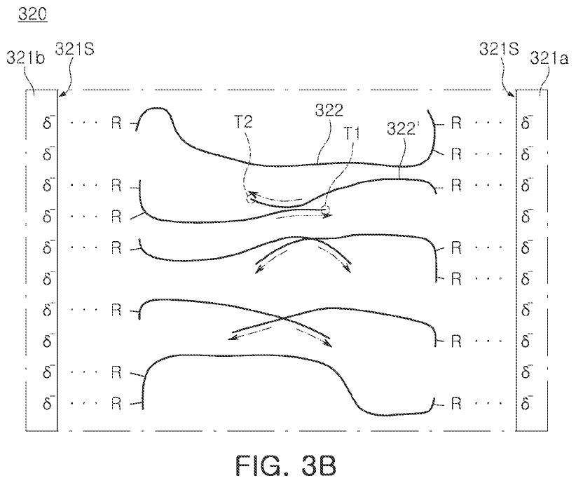

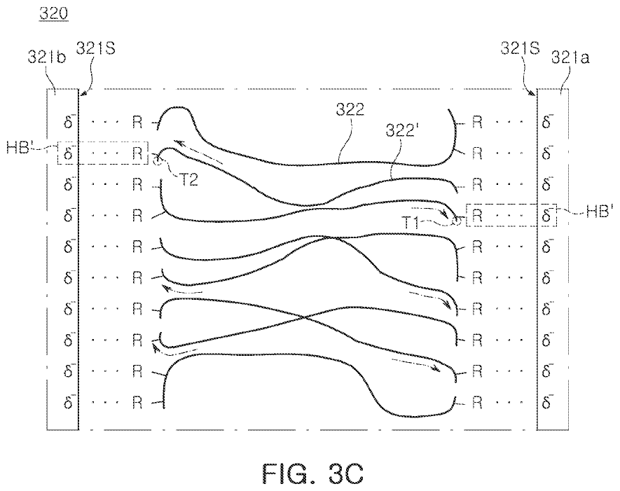

The dielectric layer 320 may be formed to cover at least portions of the first semiconductor chip 100 and the second semiconductor chip 200, respectively. The dielectric layer 320 may have an inner surface 320S1 facing the first semiconductor chip 100 and the second semiconductor chip 200 and an outer surface 320S2 opposite the inner surface 320S1. In some implementations, the dielectric layer 320 may be formed to surround a side surface of the second semiconductor chip 200 and portions of the through-electrodes 240 protruding from the rear surface S2 of the second semiconductor chip 200. The dielectric layer 320 may include nanocomposites with improved thermal and self-healing properties. This will be described in detail with reference to FIGS. 2A to 2C and 3A to 3C.

The bump structures 412 may be disposed below the second semiconductor chip 200 and electrically connected to the through-electrodes 240. The bump structures 240 may be disposed on a portion of the outer surface 320S2 of the dielectric layer 320, for example, on the lower surface of the dielectric layer 320.

The semiconductor package 10A may be connected to an external device, such as a module substrate, a main board or the like, through the bump structures 412. For example, the bump structures 412 may include a pillar portion 412P and a solder portion 412S. The pillar portion 412P includes copper (Cu) or an alloy of copper (Cu), and the solder portion 412S may include a low melting point metal, for example, tin (Sn) or an alloy (Sn—Ag—Cu) containing tin (Sn). Depending on example embodiments, the bump structures 412 may include only the pillar portion 412P or only the solder portion 412S. A protective layer 411 surrounding the bump structures 412 may be formed below the dielectric layer 320. The protective layer 411 may protect the bump structures 412 from external physical/chemical damage. The protective layer 411 may be formed using prepreg, Ajinomoto Build-up Film (ABF), FR-4, Bismaleimide Triazine (BT), Photo-Imageable Dielectric (PID), Photo Solder Resist, or the like. In some implementations, the protective layer 411 may be formed to cover the lower surface of the pillar portion 412P or may be omitted.

Hereinafter, with reference to FIGS. 2A to 2C and FIGS. 3A to 3C, the dielectric layer 320 of an example embodiment is described.

FIGS. 2A to 2B are diagrams of an example of a dielectric layer 320 according to some implementations, and FIG. 2C is a graph of an example of heat conduction characteristics of a nanocomposite according to some implementations. FIGS. 3A to 3C are diagrams of examples of self-healing characteristics of the dielectric layer 320 according to some implementations. In FIGS. 2A to 2B, the dielectric layer 320 may be a nanocomposite in which inorganic particles 321 and polymer chains 322 are combined. For example, the nanocomposite may be manufactured by adding the inorganic particles 321 to a polymer solution in which the polymer chains 322 are dissolved. The polymer solution may include a polymer resin, a solvent, a reaction initiator, a dispersant for the inorganic particles 321, and the like. The polymer resin may include, for example, polyimide, benzocyclobutene, polyhydroxystyrene, polybenzoxazoles, epoxy series, or the like. The solvent may include an organic solvent capable of dissolving the polymer resin. The reaction initiator may include a photoinitiator, a thermal initiator, or the like. The content of the inorganic particles 321 added to the polymer solution may be adjusted depending on the physical properties of the nanocomposite. For example, the inorganic particles 321 may be added in an amount ranging from about 0.1 wt % to about 50 wt %, but are not limited thereto.

The inorganic particles 321 and the polymer chains 322 may be physically and/or chemically bonded. At least one side of each of the inorganic particles 321 may have a negative polarity (δ-), and the polymer chains 322 may be physically bonded to at least one side of the inorganic particles 321. For example, the polymer chains 322 may connect surfaces 321S of the inorganic particles 321 having negative polarity (δ-) in a face-to-face manner. The polymer chains 322 may be aligned via the inorganic particles 321. The polymer chains 322 may be connected toward the inner surface 320S1 and the outer surface 320S2 of the dielectric layer 320 via the inorganic particles 321. The polymer chains 322 aligned via the inorganic particles 321 may provide a heat conduction path, thereby improving the heat dissipation characteristics of the dielectric layer 320.

The inorganic particles 321 may include at least one of, for example, aluminum nitride (AlN), aluminum oxide (Al₂O₃), silicon carbide (SiC), silicon nitride (Si₃N₄), boron nitride (BN), and silicate. The silicate may include a smectite-based material selected from the group consisting of, for example, montmorillonite, nontronite, beidellite, volkonskoite, hectorite, saponite, laponite, sauconite, megadiite, and kenyaite, a vermiculite-based material, an illite-based material, and at least one substance selected from the group consisting of derivatives thereof.

The polymer chains 322 may include at least one of epoxy, polyimide (PI), benzocyclobutene (BCB), polyhydroxy styrene (PHS), polyhydroxyalkanoate (PHB), and polybenzoxazole, but is not limited thereto. The polymer chains 322 may include functional groups (R) that are physically bonded to the inorganic particles 321. For example, the functional groups (R) may be connected to the inorganic particles 321 by hydrogen bonds (HB). The functional groups (R) may include at least one of nitrogen (N), oxygen (O), and fluorine (F). The functional groups (R) may include, for example, an amine group, a hydroxyl group, a carboxylic group, an amide group, etc.

In some implementations, the dielectric layer 320 may include the inorganic particles 321 that align the polymer chains 322 to have more improved heat conduction properties.

FIG. 2C illustrates the thermal conductivity of a nanocomposite composed of polymer resin and inorganic particles. G1 represents a change in thermal conductivity depending on the content of silicon carbide (SiC) in a nanocomposite composed of polystyrene and silicon carbide (SiC). G2 represents a change in thermal conductivity depending on the content of boron nitride (BN) in a nanocomposite composed of epoxy and boron nitride (BN). G3 represents a change in thermal conductivity depending on the aluminum oxide (Al₂O₃) content of a nanocomposite composed of polyethylene and aluminum oxide (Al₂O₃). G4 represents a change in thermal conductivity depending on the aluminum nitride (AlN) content of a nanocomposite composed of polystyrene and aluminum nitride (AlN).

In FIG. 2C, the content of inorganic particles increases and the thermal conductivity of the nanocomposite increases. FIG. 2C does not illustrate an experimental example for all of the above-described inorganic particles 321. However, the dielectric layer 320 (or nanocomposite) may have a thermal conductivity greater than thermal conductivity of a material containing only the polymer chains 322 described above. For example, the thermal conductivity of a material consisting only of polymer chains 322 is about 0.2 W/mK or less, and the thermal conductivity of the dielectric layer 320 may be about 0.4 W/mK or more. For example, the thermal conductivity of the dielectric layer 320 may range from about 0.4 W/mK to about 1.3 W/mK, from about 0.4 W/mK to about 1.2 W/mK, from about 0.4 W/mK to about 1.0 W/mK, or the like, but the present disclosure is not limited thereto.

In FIG. 2A, the dielectric layer 320 may have self-healing properties in which the cleaved polymer chains 322 are recombined with adjacent inorganic particles 321.

FIGS. 3A to 3C illustrate an example of a process in which the cleaved polymer chain 322′ is recombined with the inorganic particles 321a and 321b. In FIG. 3A, at least some (322′) of the polymer chains 322 constituting the dielectric layer 320 may be cut. The cut polymer chain 322′ may have a first end T1 and a second end T2 spaced apart from each other.

In FIG. 3B, the cut polymer chain 322′ may diffuse toward the adjacent inorganic particles 321a and 321b. For example, the first end T1 of the cut polymer chain 322′ may diffuse toward the adjacent first inorganic particle 321a. The second end T2 of the cut polymer chain 322′ may diffuse toward the adjacent second inorganic particle 321b.

In FIG. 3C, the cleaved polymer chain 322′ may be recombined (HB′) with adjacent inorganic particles 321a and 321b having negative polarity (δ-). For example, the first end T1 of the cleaved polymer chain 322′ may be recombined (HB′) with the first inorganic particle 321a. The second end T2 of the cleaved polymer chain 322′ may be recombined (HB′) with the second inorganic particle 321b. The cleaved polymer chain 322′ and the adjacent inorganic particles 321a and 321b may be recombined by hydrogen bonding.

FIGS. 4A to 4E are cross-sectional views of an example of a method of manufacturing the semiconductor package 10A of FIG. 1A according to an example of a process sequence according to some implementations. In FIG. 4A, a semiconductor wafer 100W for the first semiconductor chip 100 may be prepared. The semiconductor wafer 100W may include a plurality of first semiconductor chips 100 separated by scribe lines SL. The semiconductor wafer 100W may have a first circuit layer 120 for the first semiconductor chip 100 and a first bonding layer 130, which are formed on the first substrate 110. The first bonding layer 130 may include a first insulating layer 131 and first pads 132. The semiconductor wafer 100W may be placed on a carrier CR such that the first active surface AS1 on which the first pads 132 are disposed faces upward.

Next, a preliminary semiconductor chip 200p may be attached to the semiconductor wafer 100W. The preliminary semiconductor chip 200p may include a preliminary substrate 210p before thickness is adjusted in a back-grinding process, a second circuit layer 220 and a second bonding layer 230 disposed on the front surface of the preliminary substrate 210p, and a plurality of preliminary through-electrodes 240p buried in the preliminary substrate 210p. The preliminary semiconductor chip 200p may be disposed on the semiconductor wafer 100W such that a second active surface AS2 on which the second pads 232 are disposed faces downward. The preliminary semiconductor chip 200p may be arranged so that the second active surface AS2 is in contact with the first active surface AS1.

Then, a thermal compression process may be performed to combine the first semiconductor chip 100 and the preliminary semiconductor chip 200p. The thermal compression process may be performed in a thermal atmosphere ranging from about 100° C. to about 300° C. However, the temperature of the thermal atmosphere is not limited to the above-mentioned range and may vary.

In FIG. 4B, the preliminary substrate 210p may be etched so that at least a portion of each of the plurality of preliminary through-electrodes 240p is exposed to the rear surface S2 of the preliminary semiconductor chip 200p. The substrate 210 having a required thickness may be formed by applying a back-grinding process and an etch-back process to the preliminary substrate 210p. For example, a back-grinding process is performed to reduce the preliminary substrate 210p to a certain thickness, and by applying etch-back under appropriate conditions, the plurality of preliminary through-electrodes 240p may be sufficiently exposed.

In FIG. 4C, a preliminary dielectric layer 320p may be formed to cover the preliminary semiconductor chip 200p. The preliminary dielectric layer 320p may overall cover the rear surface S2 of the preliminary semiconductor chip 200p and the plurality of respective preliminary through-electrodes 240 exposed from the preliminary substrate 210p. The preliminary dielectric layer 320p may be formed by applying a polymer solution using a spin coating process and then curing the same. When a polymer solution is cured, a nanocomposite may be formed by combining polymer chains with inorganic particles added to the polymer solution. Accordingly, the preliminary dielectric layer 320p may include inorganic particles, and polymer chains bonded to at least one side of each of the inorganic particles and aligned throughout the thickness of the preliminary dielectric layer 320p via the inorganic particles (see FIGS. 2A and 2B).

In FIG. 4D, a polishing process is applied to the preliminary dielectric layer 320p and the plurality of preliminary through-electrodes 240p, and a flat surface consisting of the dielectric layer 320 and the plurality of through-electrodes 240 may be formed. The polishing process may include a chemical mechanical polishing (CMP) process. The dielectric layer 320 may have an inner surface 320S1 in contact with the semiconductor wafer 100W and the preliminary semiconductor chip 200p and an outer surface 320S2 exposed to the top. The outer surface 320S2 of the dielectric layer 320 and the upper surfaces of the plurality of respective through-electrodes 240 may be substantially coplanar.

In FIG. 4E, a protective layer 411 and bump structures 412 may be sequentially formed on the flat surface formed through a polishing process. The protective layer 411 may be formed using, for example, a photosensitive resin, such as PID or PSR. The bump structures 412 may include a pillar portion 412P and a solder portion 412S. Then, the semiconductor packages may be separated from each other by performing a cutting process along the scribe line (SL).

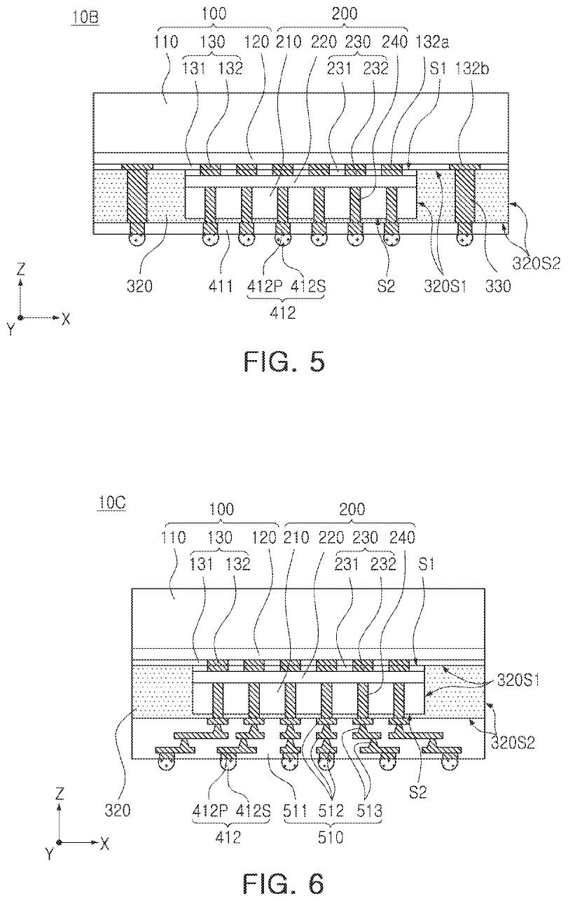

FIG. 5 is a cross-sectional view of an example of a semiconductor package according to some implementations. In FIG. 5, a semiconductor package 10B may have the same or similar features as those described with reference to FIGS. 1A to 4E, except further including through-via structures 330 penetrating the dielectric layer 320.

The through-via structures 330 may be disposed around the second semiconductor chip 200 and electrically connected to the first semiconductor chip 100. For example, the second pads 232 of the second semiconductor chip 200 are connected to first inner pads 132a of the first semiconductor chip 100, and the through-via structures 330 may be connected to first outer pads 132b of the first semiconductor chip 100. The first inner pads 132a may include a signal pad, and the first outer pads 132b may include a power and/or ground pad, but the present inventive concept is not limited thereto. According to some implementations, the through-via structures 330 may have a width greater than the width of the through-electrodes 240, but are not limited thereto.

The through-via structures 330 may be electrically connected to at least some of the bump structures 240, not vertically overlapping the second semiconductor chip 200. The through-via structures 330 may include any one of copper (Cu), nickel (Ni), titanium (Ti), aluminum (Al), gold (Au) and silver (Ag), or alloys thereof.

FIG. 6 is a cross-sectional view of an example of a semiconductor package according to some implementations. In FIG. 6, a semiconductor package 10C may have the same or similar features as those described with reference to FIGS. 1A to 5, except further including a redistribution structure 510 redistributing the through-electrodes 240. The redistribution structure 510 is disposed below the dielectric layer 320 and may include an insulating material layer 511, a redistribution pattern layer 512, and a redistribution via 513.

In some implementations, the redistribution pattern layer 512 may be directly disposed on the lower surface of the dielectric layer 320. For example, the redistribution pattern layer 512 may include an upper pattern layer directly in contact with the dielectric layer 320 and buried in the insulating material layer 511, and a lower pattern layer disposed below the insulating material layer 511. In this case, the redistribution via 513 may extend vertically within the insulating material layer 511 to connect the lower pattern layer and the upper pattern layer. In this manner, by introducing the redistribution structure 510, the layout of the bump structures 412 may be designed in various manners.

The insulating material layer 511 may be formed using a dielectric material, such as silicon oxide, silicon nitride, or silicon oxynitride, or a photosensitive resin, such as PID. The insulating material layer 511 may be formed of a plurality of layers depending on the number of layers of the redistribution pattern layer 512. Depending on a process, boundaries between at least some of the plurality of insulating material layers 511 may not be clear. According to some implementations, the pillar portion 412P of the bump structure 412 may be exposed from the insulating material layer 511, and the protective layer (‘411’ in FIG. 1A) may be formed below the redistribution structure 510 to protect the bump structure 412.

The redistribution pattern layer 512 may electrically connect the bump structures 412 and the through-electrodes 240. The redistribution pattern layer 512 may include a metallic substance including, for example, copper (Cu), aluminum (Al), silver (Ag), tin (Sn), gold (Au), nickel (Ni), lead (Pb), titanium (Ti), or alloys thereof. The redistribution pattern layer 512 may include, for example, a ground pattern, a power pattern, and a signal pattern. The signal pattern may transmit data signals transmitted from the first semiconductor chip 100 and the second semiconductor chip 200 to the outside, or transmit data signals transmitted from the outside to the first semiconductor chip 100 and the second semiconductor chip 200. The redistribution pattern layer 512 may be formed with more or fewer layers than those illustrated in the drawing (three layers).

The redistribution via 513 may extend vertically within the insulating material layer 511 and be connected to the redistribution pattern layer 512. The redistribution via 513 may have the form of a filled via in which the inside of the via hole is filled with a metal material or the form of a conformal via in which a metal material is formed along the inner wall of the via hole. The redistribution via 513 may be integrated with the redistribution pattern layer 512, but the present disclosure is not limited thereto. The redistribution via 513 may be formed in a larger number of layers than illustrated in the drawings, corresponding to the redistribution pattern layer 512.

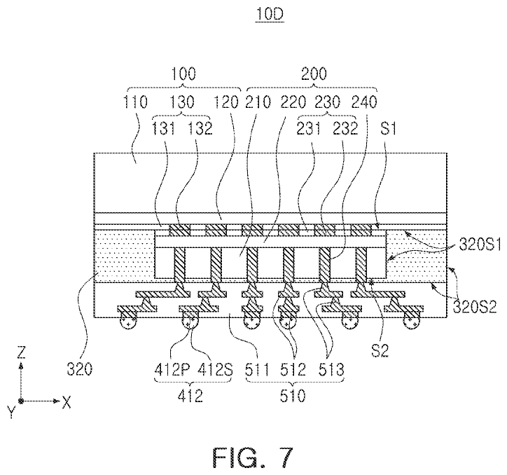

FIG. 7 is a cross-sectional view of an example of a semiconductor package according to some implementations. In FIG. 7, a semiconductor package 10D may have the same or similar features as those described with reference to FIG. 6, except that a top redistribution pattern layer 512 is spaced apart from the dielectric layer 320. The redistribution structure 510 of in this implementation may include an insulating material layer 511 disposed directly on the lower surface of the dielectric layer 320, a redistribution pattern layer 512 disposed below the insulating material layer 511, and redistribution vias 513 connected to the redistribution pattern layer 512 and the through-electrodes 240 within the insulating material layer 511. In this manner, by separating the dielectric layer 320 and the top redistribution pattern layer 512, adhesion of the redistribution pattern layer 512 may be secured, and the redistribution pattern layer 512 may be implemented with a fine pitch.

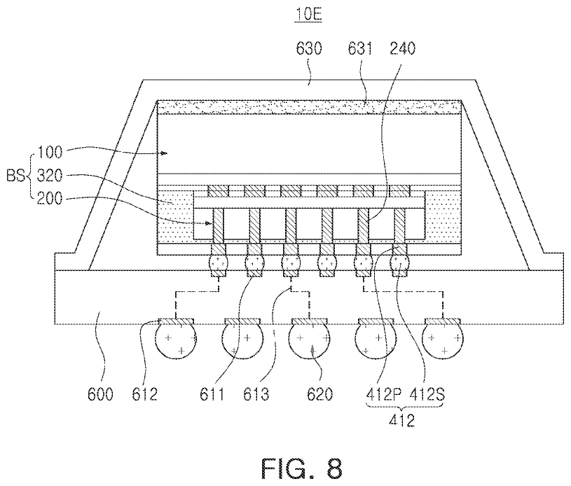

FIG. 8 is a cross-sectional view of an example of a semiconductor package according to some implementations. In FIG. 8, a semiconductor package 10E may include a bonding structure BS, a wiring board 600, and a heat dissipation structure 630. The bonding structure BS may include a first semiconductor chip 100, a second semiconductor chip 200, a dielectric layer 320 and the like, and may have the same or similar features as those described with reference to FIGS. 1A to 7.

The wiring board 600 is a support board on which the bonding structure BS is mounted, and may be a substrate for a semiconductor package, such as a printed circuit board (PCB), a ceramic substrate, a tape wiring board, or the like. The wiring board 600 may include a lower pad 612, an upper pad 611, and a wiring circuit 613 that electrically connects the lower pad 612 and the upper pad 611. A body of the wiring board 600 may contain different materials depending on the type of board. For example, when the wiring board 600 is a printed circuit board, the wiring board 600 may have a form in which an interconnection layer is additionally laminated on one or both sides of a body copper clad laminate plate or a copper clad laminate plate. The upper pad 611, the lower pad 612, and the redistribution circuit 613 may form an electrical path connecting the lower surface and the upper surface of the wiring board 600. An external connection bump 620 connected to the lower pad 612 may be disposed on the lower surface of the wiring board 600. The external connection bump 620 may include tin (Sn), indium (In), bismuth (Bi), antimony (Sb), copper (Cu), silver (Ag), zinc (Zn), lead (Pb) and/or alloys thereof.

The heat dissipation structure 630 may be disposed to cover the upper portion of the bonding structure BS. The heat dissipation structure 630 may be attached to the wiring board 600 using an adhesive (not illustrated). The adhesive may be a thermally conductive adhesive tape, thermally conductive grease, thermally conductive adhesive, or the like. The heat dissipation structure 630 may be attached to the upper portion of the bonding structure BS through a heat transfer material layer 631. The heat transfer material layer 631 may include, for example, a thermally conductive adhesive tape, thermally conductive grease, a thermally conductive adhesive, or the like.

The heat dissipation structure 630 may include a conductive material with excellent thermal conductivity. For example, the heat dissipation structure 630 may include a metal or a metal alloy including gold (Au), silver (Ag), copper (Cu), iron (Fe) or the like, or a conductive materials such as graphite, graphene, or the like. The heat dissipation structure 630 may have a shape different from the shape illustrated in the drawing, and for example, may have a shape that covers only the upper surface of the bonding structure BS.

As set forth above, according to some implementations, by introducing a dielectric layer including a nanocomposite, a semiconductor package having simplified processes and improved reliability and a method of manufacturing the same may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the subject matter of the present disclosure has been particularly shown and described with reference to different implementations, it will be understood that various changes in form and details may be made without departing from the spirit and scope of the following claims.

1. A semiconductor package comprising:
a first semiconductor chip including first pads;
a second semiconductor chip including second pads disposed on a front surface facing the first semiconductor chip and in contact with the first pads, the second semiconductor chip also including through-electrodes electrically connected to the second pads and extending to a rear surface opposite to the front surface;
a dielectric layer covering at least portions of the respective first semiconductor chip and the second semiconductor chip, the dielectric layer having an inner surface facing the first semiconductor chip and the second semiconductor chip and an outer surface opposite the inner surface; and
bump structures on a portion of the outer surface of the dielectric layer and electrically connected to the through-electrodes,
wherein the dielectric layer includes inorganic particles, and polymer chains bonded to at least one side of the respective inorganic particles, and
wherein the polymer chains are connected toward the inner surface and the outer surface via the inorganic particles.

2. The semiconductor package of claim 1,
wherein the at least one side of the respective inorganic particles have a negative polarity, and
wherein the polymer chains include functional groups physically bonded to the at least one side.

3. The semiconductor package of claim 2, wherein the functional groups are hydrogen bonded to the at least one side.

4. The semiconductor package of claim 2, wherein the functional groups include at least one of nitrogen (N), oxygen (O), and fluorine (F).

5. The semiconductor package of claim 1, wherein the inorganic particles include at least one of aluminum nitride (AlN), aluminum oxide (Al₂O₃), silicon carbide (SiC), silicon nitride (Si₃N₄), boron nitride (BN), and silicate.

6. The semiconductor package of claim 5, wherein the silicate is a smectite-based material selected from the group consisting of montmorillonite, nontronite, beidellite, volkonskoite, hectorite, saponite, laponite, sauconite, megadiite, and kenyaite, a vermiculite-based material, an illite-based material, and at least one material selected from the group consisting of derivatives thereof.

7. The semiconductor package of claim 1, wherein the polymer chains include at least one of epoxy, polyimide (PI), benzocyclobutene (BCB), polyhydroxy styrene (PHS), polyhydroxyalkanoate (PHB), and polybenzoxazole (PBO).

8. The semiconductor package of claim 1, wherein thermal conductivity of the dielectric layer is about 0.4 W/mK or more.

9. The semiconductor package of claim 1,
wherein the first semiconductor chip further includes a first insulating layer surrounding the first pads,
wherein the second semiconductor chip further includes a second insulating layer surrounding the second pads, and
wherein the second insulating layer is in contact with the first insulating layer.

10. The semiconductor package of claim 9, wherein the first insulating layer and the second insulating layer include at least one of silicon oxide (SiO), silicon nitride (SiN), and silicon carbonitride (SiCN).

11. The semiconductor package of claim 1, wherein a width of the first semiconductor chip is greater than a width of the second semiconductor chip.

12. The semiconductor package of claim 1, further comprising:
redistribution pattern layers electrically connecting the bump structures and the through-electrodes; and
an insulating material layer covering the redistribution pattern layers.

13. The semiconductor package of claim 12, wherein the insulating material layer includes a photosensitive resin.

14. The semiconductor package of claim 1, wherein at least some of the bump structures do not overlap the second semiconductor chip.

15. The semiconductor package of claim 14, further comprising through-via structures penetrating through the dielectric layer and electrically connecting the at least some of the bump structures and some of the first pads.

16. A semiconductor package comprising:
a first semiconductor chip including first pads;
a second semiconductor chip below the first semiconductor chip, the semiconductor chip including second pads in contact with the first pads and through-electrodes electrically connected to the second pads;
a dielectric layer covering at least portions of the respective first semiconductor chip and the second semiconductor chip; and
bump structures below the second semiconductor chip and electrically connected to the through-electrodes,
wherein the dielectric layer is a nanocomposite of inorganic particles and polymer chains combined with each other.

17. The semiconductor package of claim 16, wherein the inorganic particles and the polymer chains are bonded by hydrogen bonds.

18. The semiconductor package of claim 16, wherein thermal conductivity of the nanocomposite is greater than thermal conductivity of the polymer chains.

19. The semiconductor package of claim 18, wherein the thermal conductivity of the nanocomposite is about 0.4 W/mK or more.

20. A semiconductor package comprising:
a first semiconductor chip including first pads;
a second semiconductor chip below the first semiconductor chip, the second semiconductor chip including second pads in contact with the first pads and through-electrodes electrically connected to the second pads;
a dielectric layer below the first semiconductor chip and surrounding a side surface of the second semiconductor chip and portions of the through-electrodes protruding from a rear surface of the second semiconductor chip; and
bump structures below the second semiconductor chip and electrically connected to the through-electrodes,
wherein the dielectric layer includes polymer chains interconnected through inorganic particles.

21.-26. (canceled)
